(19) United States
(12) Patent Application Publication
(10) Pub. No.: US 2015/0116948 A1
(43) Pub. Date: Apr. 30, 2015

(54) ELECTRONIC DEVICE AND ELECTROMAGNETIC WAVE SHIELDING MODULE THEREOF

(71) Applicant: Wistron Corporation, New Taipei City (TW)

(72) Inventors: Chun-Hsiang Lei, New Taipei City (TW); Po-Hsien Chu, New Taipei City (TW); Chien-Ju Chen, New Taipei City (TW)

(73) Assignee: Wistron Corporation, New Taipei City (TW)

(21) Appl. No.: 14/184,713

(22) Filed: Feb. 20, 2014

(30) Foreign Application Priority Data
Oct. 25, 2013 (TW) 102138751

(51) Int. Cl. H05K 1/02; H05K 7/20

(52) U.S. Cl. CPC H05K 1/0216; H05K 1/0204; H05K 1/021; H05K 7/20136
USPC 361/720

(57) ABSTRACT

An electronic device including a circuit board, a heat generating component and an electromagnetic wave shielding module is provided. The circuit board has a ground plane. The heat generating component is disposed on the circuit board. The electromagnetic wave shielding module includes a plurality of conductive components and a heat dissipating component. The conductive components are disposed on the circuit and electrically connected to the ground plane, wherein the conductive components are arranged with intervals and surround the heat generating component. The heat dissipation component is disposed on the heat generating component and connected to the conductive components, wherein the heat dissipating component covers and contacts with the heat generating component to dissipate heat from the heat generating component and shield an electromagnetic wave generated by the heat generating component, and the electromagnetic wave is transmitted to the ground plane and drained through the conductive components.

### CROSS-REFERENCE TO RELATED APPLICATION

This application claims the priority benefit of Taiwan application serial no. 102138751, filed on Oct. 25, 2013. The entirety of the above-mentioned patent application is hereby incorporated by reference herein and made a part of this specification.

### BACKGROUND OF THE INVENTION

1. Field of the Invention

The invention relates to an electronic device and an electromagnetic wave shielding module, and more particularly to an electronic device and an electromagnetic wave shielding module having heat dissipating function.

2. Description of Related Art

For the past few years, the operation speed of electronic devices such as smart phones, tablet PCs, and notebook computers has been faster; consequently, the heat generation rate of electronic components within an electronic device is growing at the same time. In order to prevent the electronic components from being temporarily or permanently failed as a result of being overheated, it is necessary to dispose a heat dissipating component such as a heat dissipating fin in the electronic components to lower the temperature of the electronic components.

In addition, electromagnetic wave interference is one of the common problems found in electronic devices. Specifically, the electronic component in the electronic device usually generates electromagnetic wave during operation, and the electromagnetic wave affects the signal quality and working capability of other electronic components. For example, the electromagnetic wave generated by the electronic component becomes noise that interferes the antenna within the electronic device and causes the antenna to have lower capability in transmitting and receiving signals. Accordingly, it is necessary to dispose an electromagnetic wave shielding structure in the electronic device to shield the electromagnetic wave and to drain the noise quickly. However, currently the designs of electronic devices tend to be light and thin, and the disposing space within the electronic devices decreases as well. For example, the area of a motherboard within a small-sized electronic device (such as a tablet PC) is reduced. As a result, all the electronic parts are close to one another, causing more and more noise that is hard to be inhibited. Moreover, the motherboard usually adopts through holes instead of blind holes for traces; for this reason, the traces have to be arranged at the outer layer instead of the inner layer, which also causes the surface of the motherboard to lack sufficient space for disposing the electromagnetic wave shielding structure. In light of the above, when it comes to electronic device design, it is important to address the issue of how to appropriately dispose the heat dissipating component and the electromagnetic wave shielding structure within a limited disposing space in the electronic device.

### SUMMARY OF THE INVENTION

The invention provides an electronic device having an electromagnetic wave shielding module that has both heat dissipating and electromagnetic wave shielding effects such that the disposing space in the electronic device and manufacturing cost can be saved.

The invention provides an electromagnetic wave shielding module having both heat dissipating and electromagnetic wave shielding effects such that the disposing space in the electronic device and manufacturing cost can be saved.

In the invention, the electronic device includes a circuit board, a heat generating component, and an electromagnetic wave shielding module. The circuit board has a ground plane. The heat generating component is disposed on the circuit board. The electromagnetic wave shielding module includes a plurality of conductive components and a heat dissipating component. The conductive components are disposed on the circuit board and electrically connected to the ground plane, wherein the conductive components are arranged with intervals and surround the heat generating component. The heat dissipating component is disposed on the heat generating component and connected to the conductive components, wherein the heat dissipating component covers and contacts with the heat generating component to dissipate heat from the heat generating component and shield an electromagnetic wave generated by the heat generating component, and the electromagnetic wave is transmitted to the ground plane and drained through the conductive components.

In the invention, the electromagnetic wave shielding module includes a heat dissipating component and a plurality of conductive components. The heat dissipating component is for being disposed on a heat generating component of a circuit board and covers and contacts with the heat generating component. The conductive components are adapted to arranged with intervals on the circuit board and surround the heat generating component. The conductive components are adapted to be in contact with the heat dissipating component and electrically connected to a ground plane of the circuit board, such that the heat dissipating component is adapted to dissipate heat from the heat generating component and shield an electromagnetic wave generated by the heat generating component, and the electromagnetic wave is transmitted to the ground plane and drained through the conductive components.

In an embodiment of the invention, a plurality of disposing positions corresponding to the conductive components on the circuit board are respectively and independently provided with a plurality of pads electrically connected to the ground plane, for each of the conductive components to be welded on the corresponding pad by surface mount technology.

In an embodiment of the invention, the distance between two adjacent conductive components is substantially greater than or equal to 1/16 of the wavelength of the electromagnetic wave and substantially less than or equal to 1/11 of the wavelength of the electromagnetic wave.

In an embodiment of the invention, the distance between two adjacent conductive components is substantially greater than or equal to 25 millimeters and substantially less than or equal to 36 millimeters.

In an embodiment of the invention, the distance between each of the conductive components and the heat generating component is substantially greater than or equal to 1 millimeter and less than or equal to 3 millimeters.

In an embodiment of the invention, the heat generating component is in rectangular shape and has four vertices, and the position located at or adjacent to each of the vertices is provided with at least one of the conductive components.

In an embodiment of the invention, the heat dissipating component includes a main body and at least one folding wall. The main body covers and is in contact with the heat generating component. The at least one folding wall is connected to the main body and in contact with the conductive components.

In an embodiment of the invention, the heat dissipating component has a plurality of folding walls arranged with intervals, and each of the conductive components is in contact with at least one of the folding walls.

In an embodiment of the invention, each one of the conductive components has at least one clamping portion for clamping the at least one folding wall.

In an embodiment of the invention, each one of the conductive components is fixed on the circuit board by surface mounting technology.

In an embodiment of the invention, the electronic device further includes a heat dissipating fan and a heat pipe, wherein the heat pipe is connected between the heat dissipating fan and the heat dissipating component.

Based on the above, in the electromagnetic wave shielding module of the invention, the conductive components surround the heat generating component; the heat dissipating component not only dissipate the heat from the heat generating component, but also covers the heat generating component and is electrically connected to the ground plane of the circuit board by the conductive components. Accordingly, the electromagnetic wave generated by the heat generating component will be blocked by the heat dissipating component and the conductive components and transmitted to the ground plane by the heat dissipating component and the conductive components, thereby avoiding the electromagnetic wave to generate interference to another electronic component within the electronic device. Since the heat dissipating component of the invention may shield the electromagnetic wave generated by the heat generating component as described above, there is no need to dispose an extra electromagnetic wave shielding structure corresponding to the heat dissipating component, and the disposing space within the electronic device and the manufacturing cost may be effectively saved.

In order to make the aforementioned features and advantages of the invention more comprehensible, embodiments accompanying figures are described in detail below.

### BRIEF DESCRIPTION OF THE DRAWINGS

FIG. 1 is a local three-dimensional view illustrating an electronic device according to an embodiment of the invention.

FIG. 2 is a three-dimensional view illustrating parts of components of the electronic device according to FIG. 1.

FIG. 3 is a block view illustrating parts of components of the electronic device according to FIG. 1.

FIG. 4A through FIG. 4C illustrate a noise distribution caused by an electromagnetic wave generated by a heat generating component according to FIG. 1.

FIG. 5 is an enlargement view illustrating a conductive component according to FIG. 1.

### DESCRIPTION OF EMBODIMENTS

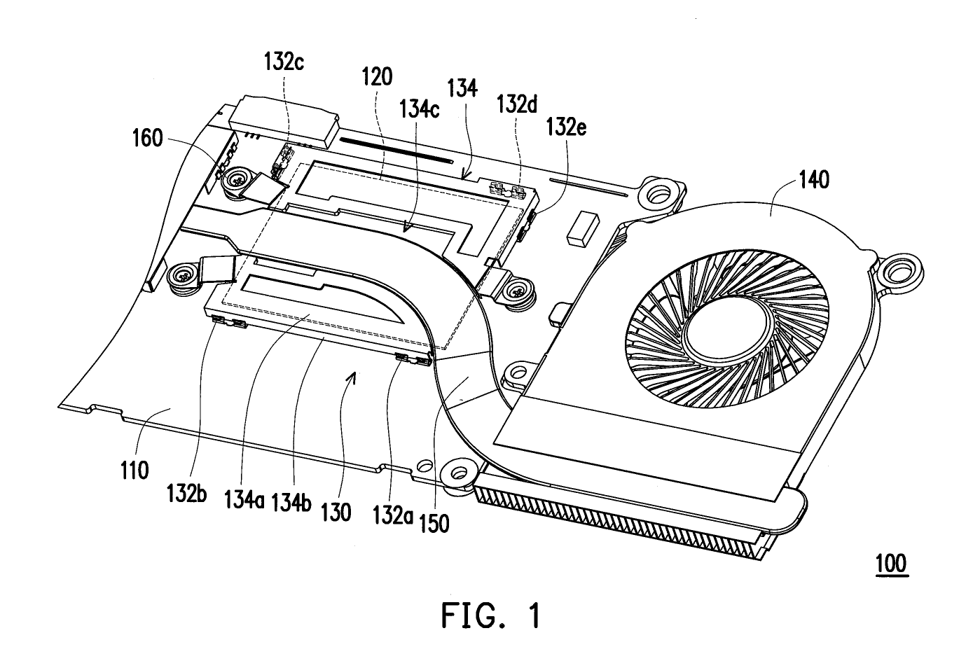

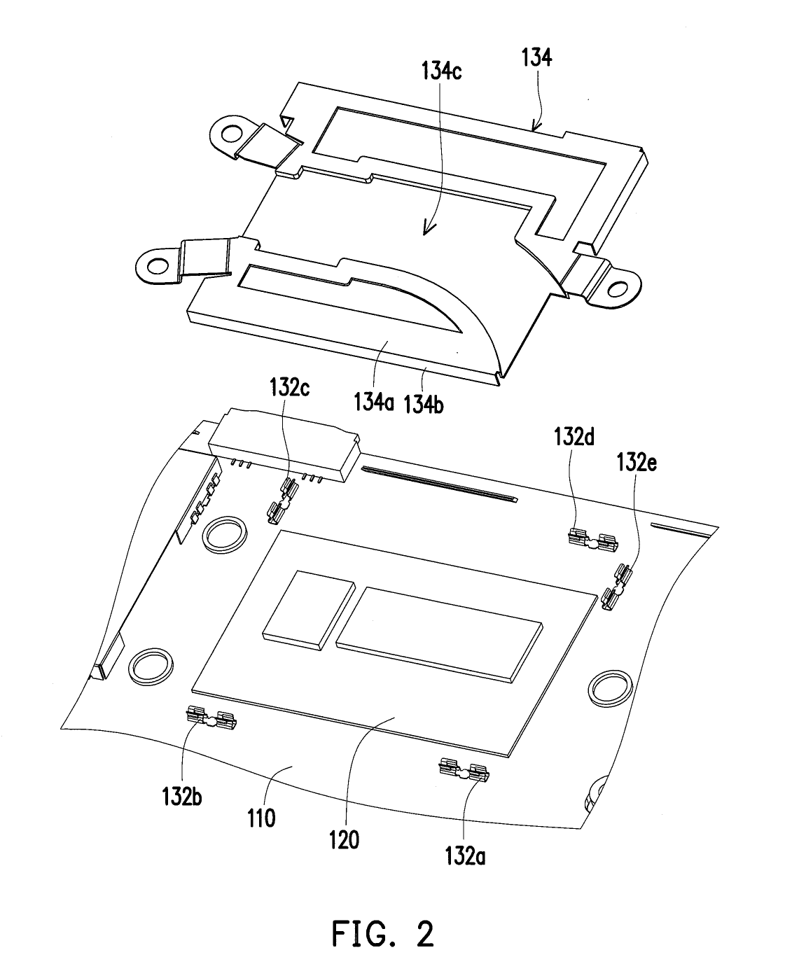

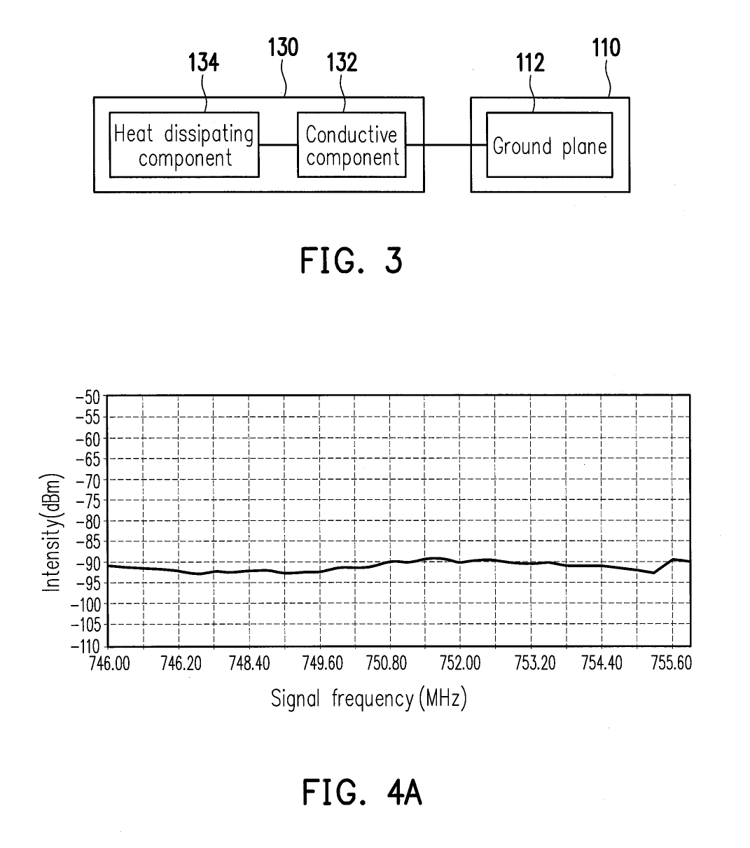

FIG. 1 is a local three-dimensional view illustrating an electronic device according to an embodiment of the invention. FIG. 2 is a three-dimensional view illustrating parts of components of the electronic device according to FIG. 1. FIG. 3 is a block view illustrating parts of components of the electronic device according to FIG. 1. To make the drawings to be clearer, only a local area within an electronic device 100 is illustrated in FIG. 1; a heat dissipating fan 140, a heat pipe 150, and a screwing member 160 in FIG. 1 are not illustrated in FIG. 2. Please refer to FIG. 1 to FIG. 3. In the embodiment, the electronic device 100 is, for example, a smart phone, a tablet PC, or a notebook computer and so on, including a circuit board 110, a heat generating component 120, an electromagnetic wave shielding module 130, a heat dissipating fan 140, and a heat pipe 150. The circuit board 110 is, for example, a motherboard within the electronic device 100 and has a ground plane 112 (illustrated in FIG. 3); the heat generating component 120 is, for example, a central processing unit (CPU) or other electronic components disposed on the circuit board 110.

The electromagnetic wave shielding module 130 includes a plurality of conductive components 132 (denoted as 132 in FIG. 3; denoted as 132a-132e respectively in FIGS. 1 and 2) and a heat dissipating component 134. The material of the conductive components 132a-132e is, for example, metal. Meanwhile, the conductive components 132a-132e are, for example, fixed on the ground circuit of the circuit board 110 by surface mounting technology. The material of the heat dissipating component 134 is, for example, metal and disposed on the heat generating component 120. The heat pipe 150 is connected between the heat dissipating component 134 and the heat dissipating fan 140 so as to dissipate the heat generated by the heat generating component 120 to the heat dissipating fan 140 for heat dissipation. The conductive components 132a-132e are connected to the ground plane 112 by the ground circuit of the circuit board 110 and surround the heat generating component 120 in an appropriate distance and intervals. The heat dissipating component 134 is connected to the conductive components 132a-134e while covering and contacting with the heat generating component 120 at the same time.

With the configuration described above, the heat dissipating component 134 not only dissipates the heat from the heat generating component 120 but also covers the heat generating component 120, and is electrically connected to the ground plane 112 of the circuit board 110 by the conductive components 132a-132e. Accordingly, the electromagnetic wave noise generated by the heat generating component 120 may be shielded by the heat dissipating component 134 and the conductive components 132a-132e and transmitted to the ground plane 112 and drained through the heat dissipating component 134 and the conductive components 132a-132e, thereby avoiding the electromagnetic wave to generate interference to other electronic components within the electronic device 100 or the surface circuit on the circuit board 110. Since the heat dissipating component 134 may shield the electromagnetic wave generated by the heat generating component 120 as described above, there is no need to dispose an extra electromagnetic wave shielding structure corresponding to the heat generating component 120, and the disposing space within the electronic device 100 and the manufacturing cost can be effectively saved.

In the embodiment, the heat dissipating component 134 as shown in FIG. 1 may not completely and closely cover the heat generating component 120. In other words, the conductive components 132a-132e may be arranged with intervals instead of fully and closely surrounding the heat generating component 120. On the one hand, the circuit layout space of the circuit board 110 may not be over taken, and relevant electronic components and circuits may still be arranged at the periphery of the heat generating component 120. On the other hand, the material cost for the heat dissipating component 134 and the conductive components 132a-132e may be lowered as well. In the embodiment, in order to fix the plurality of conductive components 132a-132e to the circuit board 110 with intervals by surface mounting technology and allow relevant electronic components and circuits to be arranged at the periphery of the heat generating component 120, a plurality of pads electrically connected to the ground plane 112 could be independently disposed only at positions on the circuit board 110 where the conductive components are predetermined to be fixed thereto, instead of forming a welding ring that is connected to all the fixing positions of the conductive components on the circuit board to allow each of the conductive components to be surface-mounted thereon. Nevertheless, in other embodiments, as long as the space for disposing the electronic components and circuits is sufficiently available, a welding ring that is connected to all the conductive components may also be formed on the circuit board. In addition, in order to allow the electromagnetic wave shielding module 130 to effectively shield the electromagnetic wave noise generated by the heat generating component 120, the distance between the conductive components 132a-132e and the arranging position of each of the conductive components 132 with respect to the heat generating component may be adjusted according to actual electromagnetic wave shielding requirement. For example, when the heat generating component 120 is in rectangular shape as shown in FIG. 2, the conductive components 132a-132e may be arranged adjacent to the four vertices of the heat generating component 120, such that the two adjacent conductive components may be arranged with an appropriate distance without being too far away from each other.

Specifically, the electromagnetic wave shielding module 130 in the embodiment, for example, performs noise shielding to the transceiving frequency (746 MHz-756 MHz) of a frequency band 13 of the long term evolution (LTE) network signal, preventing the electromagnetic wave generated by the heat generating component 120 from being leaked and affecting the antenna of the electronic device 100 to transceive the LTE signal. In other words, the electromagnetic wave shielding module 130 has to be able to shield the electromagnetic wave with 746-756 MHz frequency from the heat generating component 120. The wavelength of the electromagnetic wave of said frequency band is about 390 millimeters. Therefore, there needs to be a distance small enough between the two adjacent conductive components so that the leakage of the electromagnetic wave can be effectively prevented. The distance may be calculated through conducting experiments and tests; for example, the distance is 1/11 of the wavelength of the electromagnetic wave, preferably 1/16 of the wavelength of the electromagnetic wave. Accordingly, the distance between the two adjacent conductive components may be designed to be substantially greater than or equal to 1/16 of the wavelength of the electromagnetic wave of said frequency band and less than or equal to 1/11 of the wavelength of the electromagnetic wave of said frequency band. That is, the distance between the two adjacent conductive components 132 is substantially greater than or equal to 25 millimeters and less than or equal to 36 millimeters so as to effectively prevent the leakage of the electromagnetic wave with wavelength in 390 millimeters, wherein the two adjacent conductive components refer to the conductive component 132a and the conductive component 132b; the conductive component 132b and the conductive component 132c; the conductive component 132c and the conductive component 132d; and the conductive component 132a and the conductive component 132e. As shown in FIGS. 1 and 2, a smaller distance is kept between the adjacent conductive component 132d and the conductive component 132e so as to enhance the electromagnetic wave shielding effect, thereby avoiding a distance kept between two adjacent conductive components and the conductive component 132a or the conductive component 132c to be too long.

In addition, the distance between each of the conductive components 132 and the heat generating component 120 may be adjusted according to actual electromagnetic wave shielding requirement so as to achieve a good electromagnetic wave shielding effect. Specifically, if the distance between each of the conductive components 132 and the heat generating component 120 is too long, then the electromagnetic wave generated by the heat generating component 120 is more likely to be diffused by the lead of the circuit board 110 between each of the conductive components 132 and the heating generating component 120. In reverse, if the distance between each of the conductive components 132 and the heat generating component 120 is too short, each of the conductive components 132 will bear so much electromagnetic wave that the electromagnetic wave can hardly be transmitted to the ground plane 112 in time by the conductive component 132, leading to the leakage of the electromagnetic wave. A preferred distance between each of the conductive components 132 and the heat generating component 120 is specifically described below.

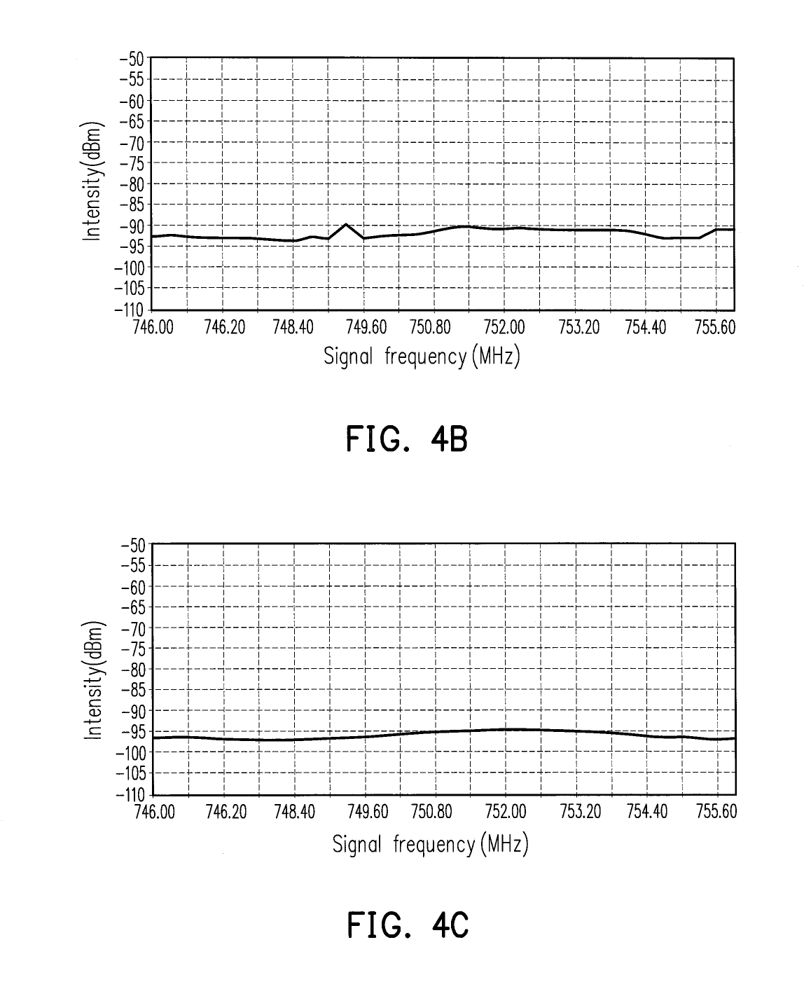

FIG. 4A through FIG. 4C illustrate a noise distribution caused by an electromagnetic wave generated by a heat generating component according to FIG. 1, wherein FIG. 4A illustrates a noise distribution that is caused when a distance less than 1 millimeter is kept between each of the conductive components 132 and the heat generating component 120. FIG. 4B illustrates a noise distribution that is caused when a distance greater than 3 millimeters is kept between each of the conductive components 132 and the heat generating component 120. FIG. 4C illustrates a noise distribution that is caused when a distance in 1-3 millimeters is kept between each of the conductive components 132 and the heat generating component 120, wherein the an average noise distribution shown in FIG. 4A is about −91 dBm. An average noise distribution shown in FIG. 4B is about −93 dBm. An average noise distribution shown in FIG. 4C is about −96 dBm. In light of the above, under the circumstances where the distance kept between each of the conductive components 132 and the heat generating component 120 is 1-3 millimeters, the average noise distribution is relatively lower. Accordingly, the distance between each of the conductive components 132 and the heat generating component 120 may be designed to be substantially greater than or equal to 1 millimeter and less than or equal to 3 millimeters (such as 2 millimeters) so that the electromagnetic wave shielding module 130 has a better noise shielding effect for the heat generating component 120.

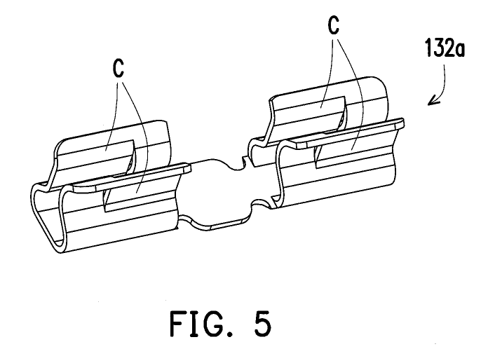

FIG. 5 is an enlargement view illustrating a conductive component according to FIG. 1. Please refer to FIGS. 1, 2, and 5. In the embodiment, the heat dissipating component 134 includes a main body 134a and a plurality of folding walls 134b. The main body 134a covers and is in contact with the heat generating component 120 and includes a recess 134c for accommodating and connecting the heat pipe 150, such that the heat generated by the heat generating component 120 is dissipated to the heat pipe 150, wherein the main body 134a is, for example, fixed on the circuit board 110 by the screwing member 160. Each of the conductive components (conducive component 132a is illustrated in FIG. 5 as an example) has at least one clamping portion C (two clamping portions are illustrated). The folding walls 134b are connected to the main body 134a and clamped by the clamping portions C so that the heat dissipating component 134 is indeed in contact with the conductive components 132a-132e. The folding walls 134b may be a closed structure of a single complete and connected folding wall 134b; alternatively, the folding walls 134b may be a non-connected structure including a plurality of folding walls 134b arranged with intervals. In other words, it is sufficient as long as the folding walls 134 are provided correspondingly for each of the conductive components. In the latter embodiment, the intervals may be utilized so as to avoid interfering the arrangement of the electronic components and circuit in the periphery of the heat generating component 120 and save materials. In other embodiments, the heat dissipating component 134 and the conductive components 132a-132e may be connected through other suitable manners; the invention provides no limitation thereto.

In summary, in the electromagnetic wave shielding module of the invention, the conductive components surround the heat generating component. The heat dissipating component not only dissipates the heat from the heat generating component but also covers the heat generating component, and is electrically connected to the ground plane of the circuit board through the conductive component as well. Accordingly, the electromagnetic wave generated by the heat generating component may be blocked by the heat dissipating component and the conductive components and transmitted to the ground plane and drained by the heat dissipating component and the conductive components, thereby avoiding the electromagnetic wave to generate interference to another electronic component and circuit within the electronic device. Since the heat dissipating component of the invention may shield the electromagnetic wave generated by the heat generating component as described above, there is no need to dispose an extra electromagnetic wave shielding structure corresponding to the heat generating component, and the disposing space within the electronic device and the manufacturing cost can be effectively saved. In addition, the distance between the conductive components, the position of each of the conductive components, and the distance between each of the conductive components and heat generating component can be adjusted according to actual electromagnetic wave shielding requirement so as to achieve a good electromagnetic wave shielding effect without significantly affecting the disposition of the electronic components and circuits in the periphery of the heat generating component.

Although the invention has been disclosed by the above embodiments, the embodiments are not intended to limit the invention. It will be apparent to those skilled in the art that various modifications and variations can be made to the structure of the invention without departing from the scope or spirit of the invention. Therefore, the protecting range of the invention falls in the appended claims.

What is claimed is:

1. An electronic device, comprising:
a circuit board having a ground plane;
a heat generating component disposed on the circuit board; and
an electromagnetic wave shielding module, comprising:
a plurality of conductive components disposed on the circuit board and electrically connected to the ground plane, wherein the conductive components are arranged with intervals and surround the heat generating component; and
a heat dissipating component disposed on the heat generating component and connected to the conductive components, wherein the heat dissipating component covers and contacts with the heat generating component to dissipate heat from the heat generating component and shield an electromagnetic wave generated by the heat generating component, and the electromagnetic wave is transmitted to the ground plane and drained through the conductive components.

2. The electronic device according to claim 1, wherein a plurality of disposing positions corresponding to the conductive components on the circuit board are respectively and independently provided with a plurality of pads electrically connected to the ground plane, for each of the conductive components to be welded to the corresponding pad by surface mounting technology.

3. The electronic device according to claim 1, wherein a distance between the two adjacent conductive components is substantially greater than or equal to 1/16 of a wavelength of the electromagnetic wave and substantially less than or equal to 1/11 of the wavelength of the electromagnetic wave.

4. The electronic device according to claim 1, wherein a distance between the two adjacent conductive components is substantially greater than or equal to 25 millimeters and substantially less than or equal to 36 millimeters.

5. The electronic device according to claim 1, wherein a distance between each of the conductive components and the heat generating component is substantially greater than or equal to 1 millimeter and substantially less than or equal to 3 millimeters.

6. The electronic device according to claim 1, wherein the heat generating component is in a rectangular shape and has four vertices, and a position located at or adjacent to each of the vertices is provided with at least one of the conductive components.

7. The electronic device according to claim 1, wherein the heat dissipating component comprises a main body and at least one folding wall, the main body covers and is in contact with the heat generating component, and the at least one folding wall is connected to the main body and in contact with the conductive components.

8. The electronic device according to claim 7, wherein the heat dissipating component comprises a plurality of folding walls arranged with intervals, and each of the conductive components is in contact with at least one of the folding walls.

9. The electronic device according to claim 7, wherein each of the conductive components comprises at least one clamping portion for clamping the at least one folding wall.

10. The electronic device according to claim 1, wherein each of the conductive components is fixed on the circuit board by surface mounting technology.

11. The electronic device according to claim 1, further comprising a heat dissipating fan and a heat pipe, wherein the heat pipe is connected between the heat dissipating fan and the heat dissipating component.

12. An electromagnetic wave shielding module, comprising:
a heat dissipating component for being disposed on a heat generating component of a circuit board and cover and contact with the heat generating component; and
a plurality of conductive components adapted to be arranged with intervals on the circuit board and surround the heat generating component, the conductive components being adapted to be in contact with the heat dissipating component and electrically connected to a ground plane of the circuit board,
such that the heat dissipating component is adapted to dissipate heat from the heat generating component and shield an electromagnetic wave generated by the heat generating component, and the electromagnetic wave is transmitted to the ground plane to be drained through the conductive components.

13. The electromagnetic wave shielding module according to claim 12, wherein a plurality of disposing positions corresponding to the conductive components on the circuit board are respectively and independently provided with a plurality of pads electrically connected to the ground plane, for each of the conductive components to be welded to the corresponding pad by surface mounting technology.

14. The electromagnetic wave shielding module according to claim 12, wherein a distance between the two adjacent conductive components is substantially greater than or equal to 1/16 of a wavelength of the electromagnetic wave and substantially less than or equal to 1/11 of the wavelength of the electromagnetic wave.

15. The electromagnetic wave shielding module according to claim 12, wherein a distance between the two adjacent conductive components is substantially greater than or equal to 25 millimeters and substantially less than or equal to 36 millimeters.

16. The electromagnetic wave shielding module according to claim 12, wherein a distance between each of the conductive components and the heat generating component is substantially greater than or equal to 1 millimeter and substantially less than or equal to 3 millimeters.

17. The electromagnetic wave shielding module according to claim 12, wherein the heat generating component is in a rectangular shape and has four vertices, and a position located at or adjacent to each of the vertices is provided with at least one of the conductive components.

18. The electromagnetic wave shielding module according to claim 12, wherein the heat dissipating component comprises a main body and at least one folding wall, the main body covers and is in contact with the heat generating component, and the at least one folding wall is connected to the main body and in contact with the conductive components.

19. The electromagnetic wave shielding module according to claim 18, wherein the heat dissipating component comprises a plurality of folding walls arranged with intervals, and each of the conductive components is in contact with at least one of the folding walls.

20. The electromagnetic wave shielding module according to claim 18, wherein each of the conductive components comprises at least one clamping portion for clamping the at least one folding wall.

21. The electromagnetic wave shielding module according to claim 12, wherein each of the conductive components is fixed on the circuit board by surface mounting technology.

22. The electromagnetic wave shielding module according to claim 12, further comprising a heat dissipating fan and a heat pipe, wherein the heat pipe is connected between the heat dissipating fan and the heat dissipating component.
